(19) United States
(12) Patent Application Publication
(10) Pub. No.: US 2015/0243649 A1
(43) Pub. Date: Aug. 27, 2015

(54) Power Transistor Die with Capacitively Coupled Bond Pad

(71) Applicant: Infineon Technologies AG, Neubiberg (DE)

(72) Inventors: Helmut Brech, Lappersdorf (DE); Matthias Zigldrum, Regensburg (DE); Albert Birner, Regensburg (DE); Richard Wilson, Morgan Hill, CA (US); Saurabh Goel, San Jose, CA (US)

(21) Appl. No.: 14/186,840

(22) Filed: Feb. 21, 2014

(51) Int. Cl. H01L 27/06; H01L 23/00; H01L 23/528; H01L 23/522; H01L 49/02

(52) U.S. Cl. CPC H01L 27/0629; H01L 23/5226; H01L 28/40; H01L 23/528; H01L 24/09; H01L 2224/0912; H01L 2924/30105; H01L 2924/1421; H01L 2924/1205; H01L 2924/13064; H01L 2924/13091; H01L 29/7816

(57) ABSTRACT

A power transistor die includes a transistor formed in a semiconductor body. The transistor has a gate terminal, an output terminal and a third terminal. The gate terminal controls a conduction channel between the output terminal and the third terminal. The power transistor die further includes a structured first metal layer disposed on and insulated from the semiconductor body. The structured first metal layer is connected to the output terminal of the transistor. The power transistor die also includes a first bond pad disposed on and insulated from the semiconductor body. The first bond pad forms an output terminal of the power transistor die and is capacitively coupled to the structured first metal layer so as to form a series capacitance between the output terminal of the transistor and the first bond pad. A power semiconductor package including the power transistor die is also provided.

### TECHNICAL FIELD

The present application relates to power transistor dies, and in particular output match networks for power transistor dies.

### BACKGROUND

Some high frequency impedance matching topologies for power transistor dies require a series capacitance in the output signal path, preferably with a high quality factor (Q) of the capacitance. Conventional designs integrate a series capacitor component on-chip with significant losses and parasitic elements, or add a discrete series capacitor component outside the die in the output signal path also with losses and parasitic elements, in addition increasing cost and reducing reliability. A higher quality and more cost-effective series capacitance solution that is both robust and effective is therefore desired.

### SUMMARY

According to an embodiment of a power transistor die, the die comprises a transistor formed in a semiconductor body, the transistor comprising a gate terminal, an output terminal and a third terminal. The gate terminal controls a conduction channel between the output terminal and the third terminal. The power transistor die further comprises a structured first metal layer disposed on and insulated from the semiconductor body. The structured first metal layer is connected to the output terminal of the transistor. The power transistor die also comprises a first bond pad disposed on and insulated from the semiconductor body. The first bond pad forms an output terminal of the power transistor die and is capacitively coupled to the structured first metal layer so as to form a series capacitance between the output terminal of the transistor and the first bond pad.

According to an embodiment of a power semiconductor package, the package comprises an electrically conductive base, an electrically insulating member, a first lead attached to the electrically insulating member, and a power transistor die. The power transistor die comprises a transistor formed in a semiconductor body, the transistor including a gate terminal, an output terminal and a third terminal. The gate terminal controls a conduction channel between the output terminal and the third terminal. The power transistor die further comprises a structured first metal layer disposed on and insulated from the semiconductor body. The structured first metal layer is connected to the output terminal of the transistor. The power transistor die also comprises a first bond pad disposed on and insulated from the semiconductor body. The first bond pad forms an output terminal of the power transistor die and is capacitively coupled to the structured first metal layer so as to form a series capacitance between the output terminal of the transistor and the first bond pad. The first lead of the package is connected to the first bond pad of the power transistor die by one or more first electrical conductors.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a circuit diagram of an embodiment of an amplifier circuit including a power transistor die with an integrated series capacitance in the output signal path of the die and an output match network which includes the series capacitance.

FIG. 2 illustrates a top-down plan view of an embodiment of a power transistor die having an integrated series capacitance in the output signal path of the die.

FIG. 3, which includes FIGS. 3A and 3B, illustrates cross-sectional views of different regions of a power transistor die having an integrated series capacitance in the output signal path of the die according to an embodiment.

FIG. 4, which includes FIGS. 4A and 4B, illustrates cross-sectional views of different regions of a power transistor die having an integrated series capacitance in the output signal path of the die according to another embodiment.

FIG. 5 illustrates a top-down plan view of an embodiment of a power semiconductor package including a power transistor die having an integrated series capacitance in the output signal path of the die and an output match network which includes the series capacitance.

### DETAILED DESCRIPTION

According to embodiments described herein, a series capacitance is integrated into the output signal path of a power transistor die without adding an additional series component and while avoiding parasitic elements. The series capacitance can be integrated into the output signal path of the die between the metallization for the output signal path and the bond pad for the output signal path, each of which is included in the power transistor die. The term ‘bond pad’ as used herein includes any electrically conductive structure included in a semiconductor die to which external electrical conductors such as bond wires, ribbons, solder balls, metal clips, etc. can be attached for providing a point of external electrical connection to the die.

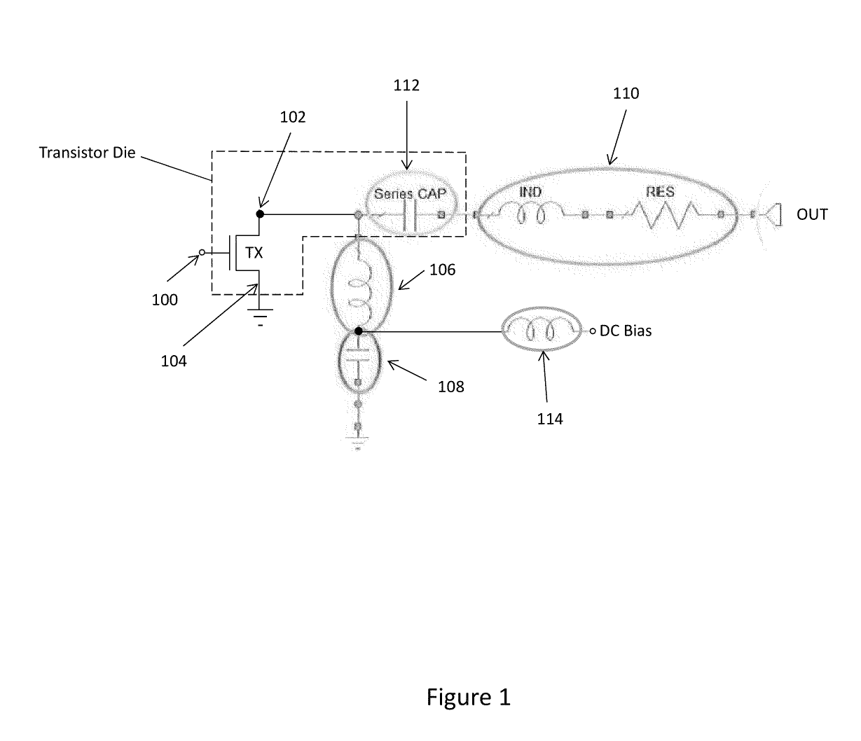

FIG. 1 illustrates a schematic diagram of an amplifier circuit which includes a power transistor (TX) such as an RF transistor and an output match network. The transistor is formed in a semiconductor body (not shown in the schematic illustration of FIG. 1) and has a gate terminal 100, an output terminal 102 and a third terminal 104. The gate terminal 100 controls a conduction channel between the output terminal 102 and the third terminal 104 as is well known in the semiconductor transistor arts. In the case of a MOSFET (metal oxide semiconductor field effect transistor) or other type of FET such as a GaN MESFET (metal semiconductor field effect transistor) or JFET (junction field effect transistor), the output terminal 102 is a drain terminal and the third terminal 104 is a source terminal. In the case of an IGBT (insulated gate bipolar transistor) or a BJT (bipolar junction transistor) such as a GaAs HBT (heterojunction bipolar transistor), the output terminal 102 is a collector terminal and the third terminal 104 is an emitter terminal.

In each case the output match network includes a shunt inductor 106 and a shunt capacitor 108 series connected between the output terminal 102 of the transistor and ground, and an inductive branch 110 coupling the transistor output 102 to an output terminal (OUT) of the circuit (e.g. at the edge of a package which includes the amplifier circuit). The inductive branch 110 is depicted in FIG. 1 as having both inductive and resistive elements (IND, RES), and is connected in series with a series capacitance 112 of the transistor. A DC feed terminal (DC Bias) of the circuit can be connected between the shunt inductor 106 and the shunt capacitor 108 by another inductive branch 114 for providing DC bias to the output terminal 102 of the transistor. The output match network provides impedance matching between the output terminal 102 of the power transistor and the output terminal (OUT) of the circuit. A corresponding input match network is not shown in FIG. 1 for ease of illustration, but could be included in the circuit for providing impedance matching between an input terminal (not shown) of the circuit and the gate terminal 100 of the transistor. The gate terminal 100 of the power transistor similarly can be capacitively coupled to the input terminal of the circuit. That is, the same type of series capacitance structures disclosed herein for the output terminal 102 of the transistor also can be used at the gate terminal 100 to capacitively couple the gate terminal 100 of the transistor to the input of the circuit.

Regardless of the particular implementation of the input and output match networks, the series capacitance 112 of the output match network is integrated with the transistor in the same semiconductor die (chip). The semiconductor die is represented by a dashed box labeled ‘Transistor Die’ in FIG. 1.

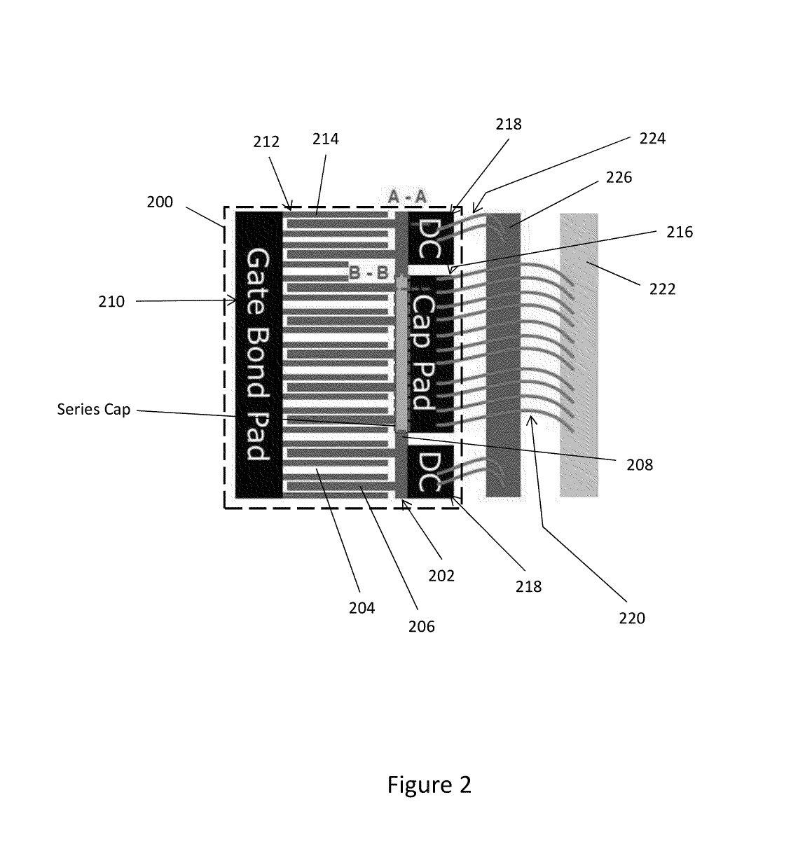

FIG. 2 illustrates a top-down plan view of an embodiment of a power transistor die 200 including an integrated series capacitance in the output signal path of the die 200. The integrated series capacitance of the die 200 can form the series capacitance 112 of the output match network shown in FIG. 1. According to the embodiment of FIG. 2, the power transistor die 200 includes a power transistor e.g. an RF transistor such as a GaN HEMT (high electron mobility transistor), Si LDMOS (lateral double diffused metal oxide semiconductor) or VDMOS (vertical double diffused MOS), a bipolar transistor, etc. formed in a semiconductor body. The transistor has a gate terminal, an output terminal and a third terminal. The output terminal can be a drain or collector terminal as previously described herein, depending on the type of transistor. The third terminal can be a source or emitter terminal also as previously described herein, again depending on the type of transistor. The gate terminal controls the conduction channel between the output terminal and the third terminal as is well known in the semiconductor transistor arts. The conduction channel forms in the semiconductor body. The semiconductor body, terminals and conduction channel of the transistor are out of view in FIG. 2.

The power transistor die 200 further includes a structured first metal layer 202 disposed on and insulated from the semiconductor body by a dielectric material 204. The structured first metal layer 202 is connected to the output terminal of the transistor. According to the embodiment of FIG. 2, the structured first metal layer 202 has a plurality of fingers 206 that extend outward from a main base 208. The finger-like extensions 206 of the structured first metal layer 202 extend in parallel and are spaced apart from one another. Individual points of connection between each of the finger-like extensions 206 and the underlying output terminal (drain/collector) of the transistor can be realized e.g. by conductive vias which extend through the dielectric material 204 that separates the structured first metal layer 202 from the underlying semiconductor body. These individual points of connection are out of view in FIG. 2, and collectively provide a conducting path between the structured first metal layer 202 and the output terminal of the transistor. The transistor die 200 also includes a gate bond pad 210 disposed on and insulated from the semiconductor body, and a structured second metal layer 212 connected to the gate pad 210 and having finger-like extensions 214 for connecting to the underlying gate terminal of the transistor. The finger-like extensions 206 of the structured first metal layer 202 are interdigitated with the finger-like extensions 214 of the structured second metal layer 212.

The power transistor die 200 also includes an output (Cap) bond pad 216 disposed on and insulated from the semiconductor body by the dielectric material 204. The output bond pad 216 forms an output terminal of the power transistor die 200 and is capacitively coupled to the structured first metal layer 202 so as to form a series capacitance between the output terminal of the transistor and the output bond pad 216. This integrated series capacitance can form the series capacitance of the output match network shown in FIG. 1. The series capacitance is realized by omitting electrical conductors such as conductive vias between the structured first metal layer 202 and the output bond pad 216. By omitting such electrical conductors in this region of the die 200, the output terminal of the transistor is electrically connected to the output bond pad 216 through a series capacitance instead of a conducting path. The region of overlap between the structured first metal layer 202 and the output bond pad 216 in which electrical conductors are omitted is illustrated with a dashed box labeled ‘Series Cap’ in FIG. 2.

The power transistor die 200 can further include a DC bond pad 218 disposed on and insulated from the semiconductor body by the dielectric material 204. The DC bond pad 218 is spaced apart from the output bond pad 216 and can have a single, continuous construction or can be segmented as shown in FIG. 2. In either case, the DC bond pad 218 forms a DC bias terminal of the power transistor die 200 and is connected to the structured first metal layer 202 through a conducting path realized by one or more electrical conductors such as conductive vias that extend through the dielectric material 204 that separates the DC bond pad 218 from the underlying structured first metal layer 202. For example, the electrical conductors can vertically connect the DC bond pad 218 to the underlying main base 208 of the structured first metal layer 202. The electrical conductors that provide the conducting path between the DC bond pad 218 and the structured first metal layer 202 are out of view in FIG. 2.

FIG. 2 also shows an electrical connection 220 between the output bond pad 216 of the transistor die 200 and an output lead 222 of a circuit package, and an electrical connection 224 between the DC bond pad 218 of the transistor die 200 and a shunt capacitor 226 of the circuit package. These electrical connections 220, 224 can be implemented using wire bonds, ribbons, metal clips or any other standard technology for connecting to a bond pad of a transistor die, and correspond to the inductances 106, 110, 114 of the output match network shown in FIG. 1.

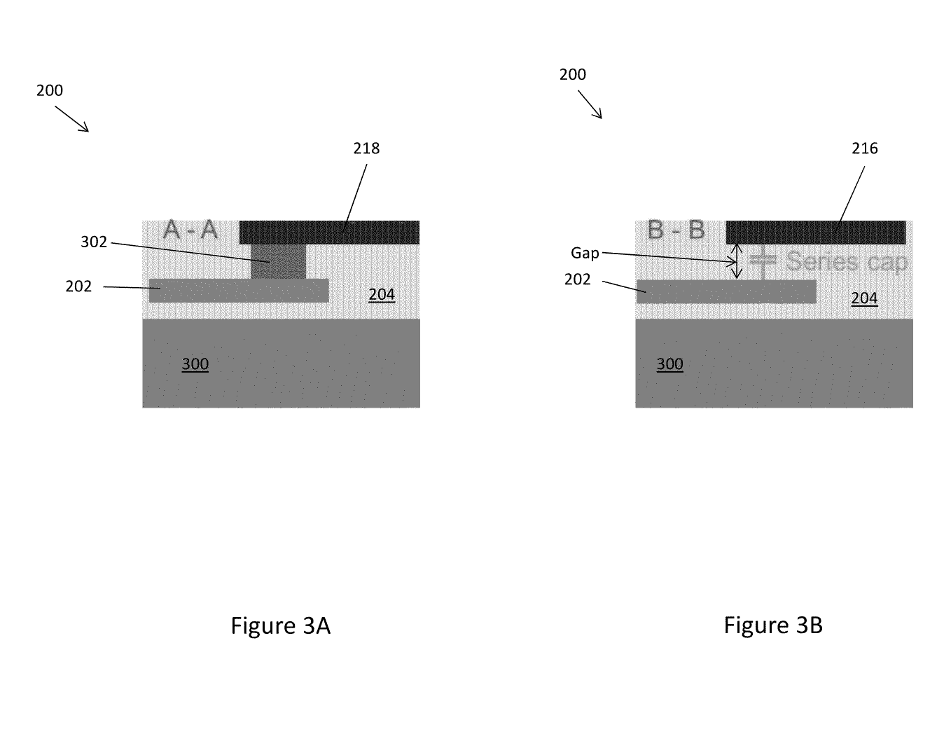

FIG. 3, which includes FIGS. 3A and 3B, illustrates respective cross-sectional views of the power transistor die 200 of FIG. 2 in different regions of the die 200 according to an embodiment. FIG. 3A illustrates a cross-sectional view of the power transistor die 200 in the region labeled A-A in FIG. 2, and FIG. 3B illustrates a cross-sectional view of the power transistor die 200 in the region labeled B-B in FIG. 2.

According to the embodiment shown in FIG. 3, the output bond pad 216 and the DC bond pad 218 are disposed in the same plane above the underlying semiconductor body 300 of the transistor die 200 and the DC bond pad 218 overlaps a different part of the underlying structured first metal layer 202 than the output bond pad 216. The DC bond pad 218 is connected to the underlying structured first metal layer 202 by one or more conductive vias 302 vertically extending between the DC bond pad 218 and the structured first metal layer 202 in the region of overlap between the DC bond pad 218 and the structured first metal layer 202. The transistor is formed in the semiconductor body 300, according to any standard transistor processing technology.

In more detail, the DC bond pad 218 is disposed on and insulated from the underlying semiconductor body 300 by a dielectric material 204 as shown in FIG. 3A. The dielectric material 204 can include one or more standard dielectric layers used in semiconductor processing such as SiN, SiO2, low-k dielectric, high-k dielectric, etc. The DC bond pad 218 is laterally spaced apart from the output bond pad 216 and forms a DC bias terminal of the power transistor die 200 as previously described herein in connection with FIG. 2. The DC bond pad 218 overlaps part of the underlying structured first metal layer 202 and is connected to the structured first metal layer 202 in this region of overlap by a conducting path formed by one or more conductive vias 302 that vertically extend between the DC bond pad 218 and the underlying structured first metal layer 202 through the intermediary dielectric material 204.

The output bond pad 216 is disposed above and overlaps a different part of the structured first metal layer 202 than the DC bond pad 218 as shown in FIG. 3B. No conducting path is provided between the output bond pad 216 and the underlying structured first metal layer 202. Instead, the output bond pad 216 is capacitively coupled to the underlying structured first metal layer 202 by the portion of the dielectric material 204 that fills the vertical gap (Gap) between the output bond pad 216 and the structured first metal layer 202 in the region of overlap between the output bond pad 216 and the structured first metal layer 202. The resulting series capacitance (Series Cap) is schematically represented in FIG. 3B with a capacitor symbol. The series capacitance is a function of the material type and thickness of the dielectric material 204 filling the vertical gap, and of the dimensions and amount of overlap between the output bond pad 216 and the structured first metal layer 202. These parameters can be selected to tune the series capacitance as desired for a particular application.

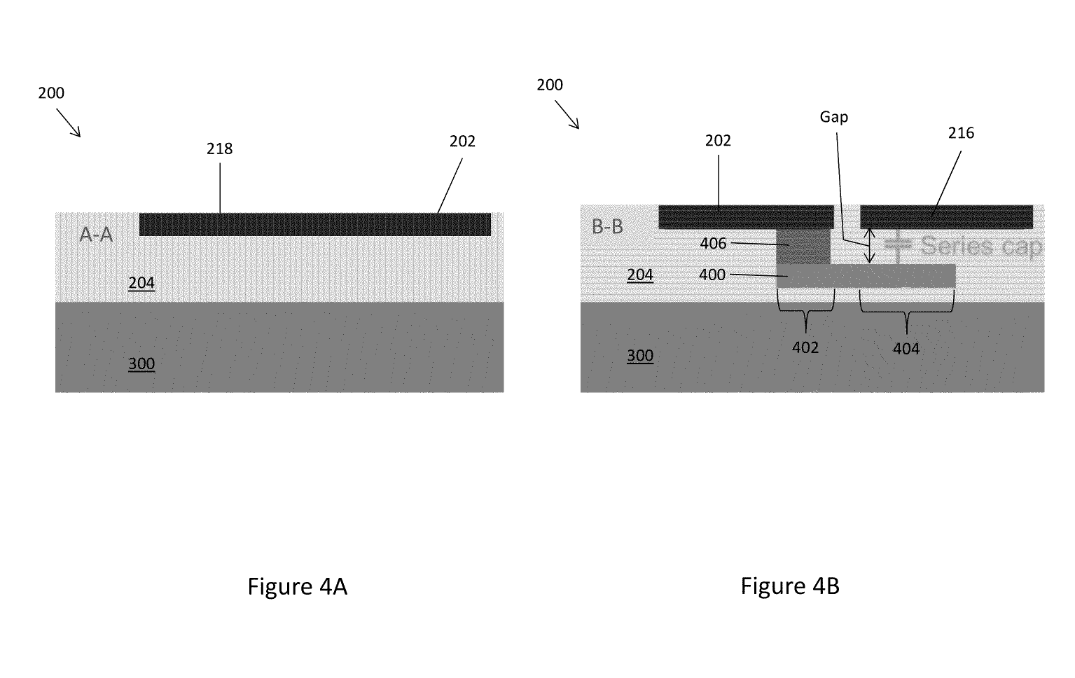

FIG. 4, which includes FIGS. 4A and 4B, illustrates respective cross-sectional views of the power transistor die 200 of FIG. 2 in different regions of the die according to another embodiment. FIG. 4A illustrates a cross-sectional view of the power transistor die 200 in the region labeled A-A in FIG. 2, and FIG. 4B illustrates a cross-sectional view of the power transistor die 200 in the region labeled B-B in FIG. 2.

According to the embodiment shown in FIG. 4, the output bond pad 216 is disposed in the same plane as the structured first metal layer 202 above the underlying semiconductor body 300 of the transistor die 200 and laterally spaced apart from the structured first metal layer 202. A second metal layer 400 is disposed on and insulated from the semiconductor body 300 by the dielectric material 204 which can include one or more standard dielectric layers used in semiconductor processing such as SiN, SiO2, low-k dielectric, high-k dielectric, etc. as previously described herein.

The second metal layer 400 is disposed partly under the structured first metal layer 202 and partly under the output bond pad 216 so that the structured first metal layer 202 overlaps a first portion 402 of the second metal layer 400 and the output bond pad 216 overlaps a second portion 404 of the second metal layer 400 as shown in FIG. 4B. Conductive vias 406 form a conducting path that connect the structured first metal layer 202 to the first portion 402 of the underlying second metal layer 400.

The output bond pad 216 is capacitively coupled to the underlying second metal layer 400 by the portion of the dielectric material 204 that fills the vertical gap (Gap) between the output bond pad 216 and the second portion 404 of the second metal layer 400 in the region of overlap between the output bond pad 216 and the second metal layer 400. The resulting series capacitance (Series Cap) is a function of the material type and thickness of the dielectric material 204 filling the vertical gap, and of the dimensions and amount of overlap between the output bond pad 216 and the second metal layer 400 as previously described herein in connection with FIG. 3.

The DC bond pad 218 is disposed on and insulated from the semiconductor body 300 by the dielectric material 204 and spaced apart from the output bond pad 216. The DC bond pad 218 forms a DC bias terminal of the power transistor die 200 as previously described herein. Further according to the embodiment of FIG. 4, the DC bond pad 218 is disposed in the same plane as the structured first metal layer 202 and the output bond pad 216. Also according to this embodiment, the DC bond pad 218 and the structured first metal layer 202 are of a single, continuous construction as shown in FIG. 4A. That is, the DC bond pad 218 is a constituent, integral part of the structured first metal layer 202 in this embodiment.

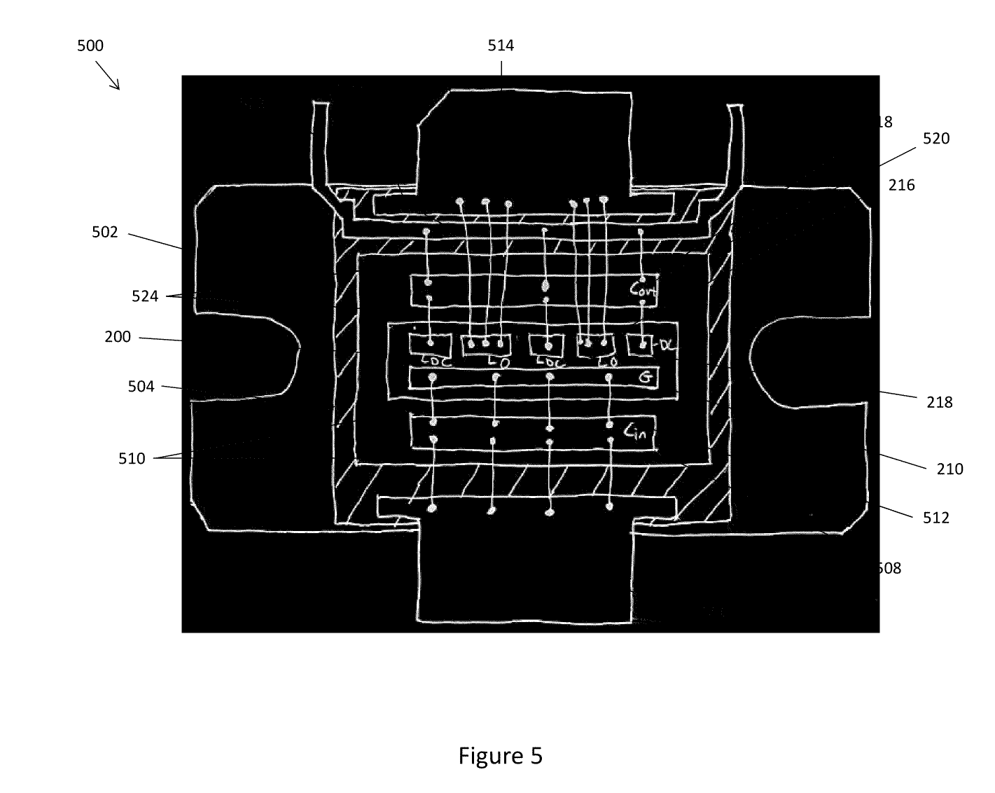

FIG. 5 illustrates a top-down plan view of a power semiconductor package 500 that includes an electrically conductive base 502 such as a copper flange, an electrically insulating member 504 such as a ceramic window attached to the base 502 and a power transistor die 200 of the kind previously described herein attached to the base 502. That is the power transistor die 200 comprises a transistor formed in a semiconductor body, the transistor including a gate terminal, an output (drain/collector) terminal, and a third terminal (source/emitter), the gate terminal controlling a conduction channel between the output terminal and the third terminal. The die 200 further comprises a structured first metal layer disposed on and insulated from the semiconductor body, the structured first metal layer being connected to the output terminal of the transistor.

The power transistor die 200 also comprises an output (0) bond pad 216 disposed on and insulated from the semiconductor body. The output bond pad 216 forms an output terminal of the power transistor die 200 and is capacitively coupled to the structured first metal layer included in the die 200 so as to form a series capacitance between the output terminal of the transistor and the output bond pad 216 as previously described herein. The output bond pad 216 faces away from the base 502, and can be of a single continuous construction or segmented as shown in FIG. 5. A source bond pad (out of view) is disposed on the opposite side of the die 200 and connected to the third (source/emitter) terminal of the transistor and attached to the base 502 of the power semiconductor package 500. A gate (G) bond pad 210 is disposed on the same side of the die 200 as the output bond pad 216 and spaced apart from the output bond pad 216. The gate bond pad 210 is connected to the gate terminal of the transistor.

The power semiconductor package 500 further includes an input lead 506 attached to the electrically insulating member 504 and capacitively coupled to the gate pad 210 of the transistor die 200 through an input shunt capacitor (Cin) 508 by one or more input electrical conductors 510. The input shunt capacitor 508 is spaced apart from the power transistor die 200 and has a first terminal 512 facing away from the base 502 and to which the input electrical conductors 510 are attached, and a second terminal (out of view) facing the base 502 and attached to the base 502.

The power semiconductor package 500 also includes an output lead 514 attached to the electrically insulating member 504 and connected to the output bond pad 216 of the transistor die 200 by one or more output electrical conductors 516. An output shunt (Cout) capacitor 518 of an output match network e.g. of the kind shown in FIG. 1 is spaced apart from the power transistor die 200 and has a first terminal 520 facing away from the base 502 and a second terminal (out of view) facing the base 502 and attached to the base 502. According to this embodiment, the power transistor die 200 further comprises a DC bond pad 218 disposed on and insulated from the semiconductor body of the die 200 and spaced apart from the output bond pad 216 of the die 200. The DC bond pad 218 forms a DC bias terminal of the power transistor die 200 and is connected to the structured first metal layer of the die 200 through a conducting path as previously described herein. The DC bond pad 218 is also connected to the second terminal 520 of the output shunt capacitor 518 which in turn is connected to a DC bias lead 522 of the package 500 by one or more DC bias electrical conductors 524. The DC bond pad 218 faces away from the base 502 of the package 500 and can be of a single continuous construction or segmented as shown in FIG. 5, depending on the arrangement of the output and DC bias leads 514, 522 of the package 500. The base 502 of the package 500 can be grounded or tied to another potential in this configuration so that the second terminal (out of view) of the input and output shunt capacitors 508, 518 and the third (source/emitter) terminal of the transistor are at the same potential.

The power transistor die 200 can have any of the constructions previously described herein e.g. in accordance with FIGS. 2 through 4, or other construction so long as the output pad 216 of the transistor die 200 is capacitively coupled to the structured first metal layer of the die 200 to form an internal (integrated) series capacitance between the output terminal of the transistor and the output bond pad 216 of the die 200. This (integrated) series capacitance (Series Cap in FIGS. 3 and 4) forms the shunt capacitance of the output match network of the power semiconductor package 500 shown in FIG. 5.

Terms such as “first”, “second”, and the like, are used to describe various elements, regions, sections, etc. and are not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power transistor die, comprising:
a transistor formed in a semiconductor body, the transistor comprising a gate terminal, an output terminal and a third terminal, the gate terminal controlling a conduction channel between the output terminal and the third terminal;
a structured first metal layer disposed on and insulated from the semiconductor body, the structured first metal layer being connected to the output terminal of the transistor; and
a first bond pad disposed on and insulated from the semiconductor body, the first bond pad forming an output terminal of the power transistor die and being capacitively coupled to the structured first metal layer so as to form a series capacitance between the output terminal of the transistor and the first bond pad.

2. The power transistor die of claim 1, wherein the first bond pad is disposed above and overlaps part of the structured first metal layer, and wherein the first bond pad is capacitively coupled to the structured first metal layer by a dielectric material filling a gap between the first bond pad and the structured first metal layer in the region of overlap between the first bond pad and the structured first metal layer.

3. The power transistor die of claim 2, further comprising:
a second bond pad disposed on and insulated from the semiconductor body and spaced apart from the first bond pad, the second bond pad forming a DC bias terminal of the power transistor die and being connected to the structured first metal layer through a conducting path.

4. The power transistor die of claim 3, wherein the first bond pad and the second bond pad are disposed in the same plane, wherein the second bond pad overlaps a different part of the structured first metal layer than the first bond pad, and wherein the second bond pad is connected to the structured first metal layer by a plurality of conductive vias extending between the second bond pad and the structured first metal layer in the region of overlap between the second bond pad and the structured first metal layer.

5. The power transistor die of claim 1, wherein the first bond pad is disposed in the same plane as the structured first metal layer and spaced apart from the structured first metal layer, the power transistor die further comprising:
a second metal layer disposed on and insulated from the semiconductor body, the second metal layer being disposed partly under the structured first metal layer and partly under the first bond pad so that the structured first metal layer overlaps a first portion of the second metal layer and the first bond pad overlaps a second portion of the second metal layer; and
a plurality of conductive vias connecting the structured first metal layer to the first portion of the second metal layer,
wherein the first bond pad is capacitively coupled to the second metal layer by a dielectric material filling a gap between the first bond pad and the second portion of the second metal layer in the region of overlap between the first bond pad and the second metal layer.

6. The power transistor die of claim 5, further comprising:
a second bond pad disposed on and insulated from the semiconductor body and spaced apart from the first bond pad, the second bond pad forming a DC bias terminal of the power transistor die and being connected to the structured first metal layer through a conducting path.

7. The power transistor die of claim 6, wherein the second bond pad and the structured first metal layer are in the same plane, and wherein the second bond pad and the structured first metal layer are of a single, continuous construction.

8. The power transistor die of claim 1, further comprising:
a second bond pad disposed on and insulated from the semiconductor body and spaced apart from the first bond pad, the second bond pad forming a DC bias terminal of the power transistor die and being connected to the structured first metal layer through a conducting path.

9. The power transistor die of claim 1, wherein the transistor is an RF transistor.

10. A power semiconductor package, comprising:
an electrically conductive base;
an electrically insulating member attached to the base;
a power transistor die attached to the base and comprising:
a transistor formed in a semiconductor body, the transistor including a gate terminal, an output terminal and a third terminal, the gate terminal controlling a conduction channel between the output terminal and the third terminal;
a structured first metal layer disposed on and insulated from the semiconductor body, the structured first metal layer being connected to the output terminal of the transistor; and
a first bond pad disposed on and insulated from the semiconductor body and facing away from the base, the first bond pad forming an output terminal of the power transistor die and being capacitively coupled to the structured first metal layer so as to form a series capacitance between the output terminal of the transistor and the first bond pad; and
a first lead attached to the electrically insulating member and connected to the first bond pad of the power transistor die by one or more first electrical conductors.

11. The power semiconductor package of claim 10, wherein the first bond pad is disposed above and overlaps part of the structured first metal layer, and wherein the first bond pad is capacitively coupled to the structured first metal layer by a dielectric material filling a gap between the first bond pad and the structured first metal layer in the region of overlap between the first bond pad and the structured first metal layer.

12. The power semiconductor package of claim 11, further comprising:
a capacitor spaced apart from the power transistor die and having a first terminal facing away from the base and a second terminal facing the base and connected to the base,
wherein the power transistor die further comprises a second bond pad disposed on and insulated from the semiconductor body and spaced apart from the first bond pad, the second bond pad forming a DC bias terminal of the power transistor die and being connected to the structured first metal layer through a conducting path,
wherein the second bond pad is connected to the second terminal of the capacitor by one or more second electrical conductors.

13. The power semiconductor package of claim 12, wherein the first bond pad and the second bond pad are disposed in the same plane, wherein the second bond pad overlaps a different part of the structured first metal layer than the first bond pad, and wherein the second bond pad is connected to the structured first metal layer by a plurality of conductive vias extending between the second bond pad and the structured first metal layer in the region of overlap between the second bond pad and the structured first metal layer.

14. The power semiconductor package of claim 10, wherein the first bond pad is disposed in the same plane as the structured first metal layer and spaced apart from the structured first metal layer, and wherein the power transistor die further comprises:
a second metal layer disposed on and insulated from the semiconductor body, the second metal layer being disposed partly under the structured first metal layer and partly under the first bond pad so that the structured first metal layer overlaps a first portion of the second metal layer and the first bond pad overlaps a second portion of the second metal layer; and
a plurality of conductive vias connecting the structured first metal layer to the first portion of the second metal layer,
wherein the first bond pad is capacitively coupled to the second metal layer by a dielectric material filling a gap between the first bond pad and the second portion of the second metal layer in the region of overlap between the first bond pad and the second metal layer.

15. The power semiconductor package of claim 14, further comprising:
a capacitor spaced apart from the power transistor die and having a first terminal facing away from the base and a second terminal facing the base and connected to the base,
wherein the power transistor die further comprises a second bond pad disposed on and insulated from the semiconductor body and spaced apart from the first bond pad, the second bond pad forming a DC bias terminal of the power transistor die and being connected to the structured first metal layer through a conducting path,
wherein the second bond pad is connected to the second terminal of the capacitor by one or more second electrical conductors.

16. The power semiconductor package of claim 15, wherein the second bond pad and the structured first metal layer are in the same plane, and wherein the second bond pad and the structured first metal layer are of a single, continuous construction.

17. The power semiconductor package of claim 10, further comprising:
a capacitor spaced apart from the power transistor die and having a first terminal facing away from the base and a second terminal facing the base and connected to the base,
wherein the power transistor die further comprises a second bond pad disposed on and insulated from the semiconductor body and spaced apart from the first bond pad, the second bond pad forming a DC bias terminal of the power transistor die and being connected to the structured first metal layer through a conducting path,
wherein the second bond pad is connected to the second terminal of the capacitor by one or more second electrical conductors.

18. The power semiconductor package of claim 10, wherein the transistor is an RF transistor.
